(19) United States
(12) Patent Application Publication
(10) Pub. No.: US 2003/0082862 A1
(43) Pub. Date: May 1, 2003

(54) Method for fabricating a gate layer stack for an integrated circuit configuration

(76) Inventors: Frank Richter, Dresden (DE); Ulrike Gruning-V. Schwerin, Munchen (DE); Ulrike Bewersdorff-Sarlette, Radebeul (DE); Alexander Ruf, Dresden (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/284,777

(22) Filed: Oct. 31, 2002

(30) Foreign Application Priority Data
Oct. 31, 2001 (DE) 101 53 619.4

(51) Int. Cl. H01L 21/336; H01L 21/8234; H01L 21/3205

(52) U.S. Cl. 438/197; 438/303; 438/592

(57) ABSTRACT

During the fabrication of patterned gate layer stacks for transistors in integrated semiconductor circuits, a lower and an upper gate layer are deposited. Both layers are patterned laterally. The lower gate layer made of polysilicon is oxidized to bind impurity ions that have indiffused near its sidewall spatially in an oxide. If the upper gate layer is composed of tungsten, the latter can be damaged during the oxidation and the conductivity of the gate layer stack can be reduced. Sidewall coverings deposited onto the upper gate layer before the oxidation also do not afford protection against a tungsten oxidation if the sidewall oxide grows from the side more deeply into the gate layer stack than as far as the inner sides of the sidewall coverings. The patterning of the lower gate layer is divided into two separate process steps between which the sidewall coverings are formed. As a result, the sidewall coverings extend right into the lower gate layer and prevent a tungsten oxidation even in the case of inwardly overgrowing sidewall oxide.

### BACKGROUND OF THE INVENTION

### Field of the Invention

The invention relates to a method for fabricating a patterned gate layer stack for an integrated circuit configuration. The method has the following order of steps:

a) provision of a semiconductor substrate;

b) formation of a gate oxide layer on the semiconductor substrate;

c) deposition of a lower gate layer;

d) deposition of an upper gate layer having a higher electrical conductivity than the lower gate layer;

e) patterning at least of the upper gate layer;

f) deposition of a protective layer at least onto sidewalls of the patterned upper gate layer for the purpose of forming sidewall coverings; and

g) further patterning of the gate layer stack at least until the gate oxide layer is reached.

The invention furthermore relates to an integrated circuit configuration having a semiconductor substrate and a patterned gate layer stack disposed thereon. The gate layer stack has a lower gate layer, which is disposed above a gate oxide layer on the semiconductor substrate, and an upper gate layer having a higher electrical conductivity than the lower gate layer. The patterned gate layer stack has sidewall coverings, which cover at least sidewalls of the upper gate layer and whose lower edges are disposed above the gate oxide layer and at a distance from the gate oxide layer.

During the production of integrated semiconductor circuits, transistors, usually metal oxide semiconductor field-effect transistors (MOSFETs) are fabricated on a semiconductor substrate. In order to form the transistors, a sequence of a plurality of layers is deposited onto the semiconductor substrate over the whole area and then patterned laterally with the aid of etching processes that are preceded by a lithographic mask exposure. MOSFETs have a gate electrode between the source electrodes implanted into the semiconductor substrate, the gate electrode being formed as a layer stack above the gate oxide situated on the substrate. The gate layer stack has a lower gate layer, usually composed of polysilicon, and an upper gate layer, which has a higher conductivity than polysilicon and is often composed of tungsten silicide. Situated above the upper gate layer there is usually also a covering layer that protects covered area regions of the layer stack during the etching processes. The upper gate layer is necessary in order that the conductivity of the layer stack patterned in the form of word lines is increased overall in the lateral direction. In dynamic random access memories (DRAMs), the upper gate layer is produced from tungsten silicide, which, however, entails only a limited increase in the conductivity. In the case of gate electrodes of logic transistors, the upper gate layer is in part also produced by siliciding the polysilicon. However, in the fabrication of semiconductor circuits which have both memory regions and logic regions and in which the transistors in the memory region are produced in pairs at a small distance from one another and with a common source/drain electrode, subsequent siliciding of the polysilicon in order to form the upper gate layer is not possible for process engineering reasons.

Therefore, in memory regions of integrated circuits, transistors are being fabricated more and more frequently with an upper gate layer made of metallic tungsten, which has an even higher electrical conductivity than tungsten silicide. Tungsten has the disadvantage, however, of forming partly volatile tungsten oxide at temperatures above 350° C. even with very small quantities of oxygen. Moreover, there is the risk of tungsten-containing compounds evaporating in hydrogen-containing atmospheres at temperatures even below 700° C. As a result, the upper gate layer made of tungsten is attacked and the electrical conductivity of the gate electrode is impaired. The risk of oxidation of the tungsten exists particularly when, after the etching, i.e. lateral patterning of the gate layer stacks, the sidewalls of the lower layer made of polysilicon are oxidized in an oxygen-containing atmosphere in order to spatially bind ions or other contaminants that have entered into the polysilicon and thus to ensure the quality of the gate electrode.

At the same time as the sidewall oxidation, a silicon dioxide layer is formed, or reinforced still further, on the semiconductor substrate between the regions covered by the gate structures. The regions made of silicon dioxide likewise serve for preventing the occurrence of leakage currents. After the conclusion of the oxidation process, spacers are produced by the patterned gate layer stack being covered with a conformal nitride layer which is subsequently etched anisotropically in the direction perpendicular to the substrate surface and therefore remains exclusively on the sidewalls of the gate layer stacks. As a result, the gate electrode, whose upper gate layer is already protected by the covering layer, is also protected in the lateral direction.

The spacer is not yet present during the sidewall oxidation. If the upper gate layer is composed of tungsten, the latter is attacked during the oxidation; the gate electrode becomes unusable.

U.S. Pat. No. 6,107,171 describes a method for fabricating a patterned gate layer stack in which two different protective layers are applied on each side wall. The inner protective layer serves to prevent an oxidation of the tungsten during the sidewall oxidation. The outer protective layer performs the function of a spacer, which, before the implantation of the source and drain electrodes, is intended to ensure a sufficient lateral distance between the electrode implantations and the channel region below the gate electrode. The inner protective layer is intended to prevent an oxidation of the upper gate layer made of tungsten, but at the same time a sidewall oxidation of the lower gate layer made of polysilicon must take place. Therefore, in the method described in the above document, it is provided that first only the upper gate layer (together with a covering layer and a thin intermediate layer) is etched and then the first inner protective layer is applied and patterned to form first sidewall coverings. The lower gate layer made of polysilicon is subsequently patterned, the covering layer and the first spacers serving as an etching mask. The latter surround the tungsten-containing upper gate layer during the sidewall oxidation of the polysilicon and at the same time protect the sidewalls of the upper layer made of tungsten.

The method proposed has the disadvantage that, depending on the duration of the oxidation process and depending on the width of the first spacers, reliable protection against an oxidation of the tungsten is not always achieved. If the sidewall oxidation leads to an oxide layer which extends from the side further inward into the polysilicon than as far as the inner sides of the sidewall coverings of the tungsten layer, then the silicon dioxide formed reaches the underside of the upper gate layer made of tungsten. Even if an intermediate layer made of tungsten nitride, for example, is also situated below the gate layer, which intermediate layer is often used to prevent a chemical reaction with polysilicon during the tungsten deposition, oxidation of tungsten is still possible. This is because during later method steps that require a temperature increase, there arises from the layer sequence of tungsten on tungsten nitride a common layer predominantly made of tungsten whose silicide proportion continuously decreases from bottom to top. This layer also largely contains tungsten at its underside, which tungsten is exposed to an oxidation from below in the case of sidewall oxide reaching it.

Therefore, in order to prevent such an oxidation, the sidewall covering of the tungsten must be dimensioned to be very wide, or the oxidation process is permitted to be carried out only over a very short time duration. Therefore, however, that contaminants and ions which are situated at a somewhat larger distance from the sidewall are no longer spatially bound and leakage currents into the semiconductor substrate are no longer reliably prevented.

### SUMMARY OF THE INVENTION

It is accordingly an object of the invention to provide a method for fabricating a gate layer stack for an integrated circuit configuration that overcomes the above-mentioned disadvantages of the prior art devices of this general type, which reliably prevents impairment of the electrical conductivity of the upper gate layer without losses in the protection of the sidewalls of the lower gate layer.

With the foregoing and other objects in view there is provided, in accordance with the invention, a method for fabricating a gate layer stack for an integrated circuit configuration. The method includes providing a semiconductor substrate, forming a gate oxide layer on the semiconductor substrate, depositing a lower gate layer on the gate oxide layer, depositing an upper gate layer having a higher electrical conductivity than the lower gate layer above the lower gate layer, and patterning at least the upper gate layer resulting in a patterned upper gate layer. An upper part of a layer thickness of the lower gate layer is also patterned. A protective layer is deposited at least onto sidewalls of the patterned upper gate layer and of the upper part of the layer thickness of the lower gate layer resulting in a formation of sidewall coverings. The lower gate layer, the upper gate layer, and the protective layer define the gate layer stack, and the gate layer stack is further patterned at least until the gate oxide layer is reached and the lower gate layer is patterned only in a lower part of the layer thickness.

With regard to the method, the object is achieved in that the lower gate layer, is patterned in an upper part of its layer thickness and, is covered with the protective layer in the upper part of its layer thickness, and in that, the lower gate layer is patterned only in the lower part of its layer thickness.

According to the invention, the etching of the lower gate layer is split into two process steps, in which the lower gate layer is in each case patterned only in a partial region of its layer thickness, and the process step of producing the protective layer, i.e. the sidewall coverings, is inserted between these two partial steps. The consequence of this is that the sidewall covering formed ends neither at a height above the lower gate layer nor below it, but rather in it. As a result, the oxide formed below the sidewall covering does not reach the upper gate layer even in the event of a relatively long oxidation duration.

During the patterning step, the upper gate layer and an upper partial thickness of the lower gate layer are etched, and so too are, if present, an intervening barrier layer and a covering layer made of nitride, for example, which lies at the very top. The gate electrode is then patterned down to a lower part of the lower gate layer and the gate oxide layer. Afterward, the integrated circuit configuration is covered with a thin, conformal protective layer made of silicon nitride, for example. The subsequent anisotropic etching operation removes the protective layer except on the sidewalls of the gate electrode thus far patterned. On account of the method according to the invention, the sidewall covering formed now extends to a height below the underside of the upper gate layer or, if present, below the underside of the barrier layer. The sidewall covering reaches into the lower gate layer made of polysilicon. If afterward, through the remaining patterning of the gate layer stack, the lower gate layer is also patterned in the lower partial region of its layer thickness, then it becomes accessible from the side only in the height region below the sidewall covering formed. Therefore, in the case of a sidewall oxidation, only the lower region of the polysilicon layer is converted into silicon dioxide that grows into the polysilicon (and outward to approximately the same extent).

On account of the method according to the invention, the silicon dioxide growing into the polysilicon no longer reaches the underside of the upper gate layer or of the barrier layer, since these are additionally removed at least by the height difference of the upper partial thickness of the polysilicon layer from the growing-in silicon oxide. As a result, an oxidation of the tungsten-containing upper gate electrode is reliably prevented even in the event of lateral propagation of the boundary between polysilicon and silicon dioxide beyond the layer thickness of the sidewall covering. It is not necessary to shorten the duration of the sidewall oxidation.

Preferably, an etchant for patterning the upper gate layer is exchanged for an etchant for patterning the lower gate layer, with which the lower gate layer is patterned in the upper part of its layer thickness. In the case of an anisotropic dry etching with the aid of a reactive ion etching (REI) method, although the etching can be carried out in the same etching chamber, the feeding of the etchant for patterning the upper gate layer is ended and another etchant for patterning the lower gate layer is fed instead. As a result of this the method differs from merely lengthening the etching process for etching for instance the upper gate layer, which is referred to as over-etching and is intended merely to serve to ensure complete removal of the upper gate layer even at steps.

Preferably, the gate layer stack is patterned by dry etching the etchant chlorine is exchanged for hydrogen bromide. Chlorine is suitable in conjunction with oxygen for etching nitride and metal or metal silicide layers selectively with respect to polysilicon, whereas the latter can be etched by hydrogen bromide (HBr).

Preferably, the sidewalls of the lower gate layer are oxidized below the lower edges of the sidewall coverings. As a result, a sidewall oxide is formed up to the height of the lower edge of the protective layer, which forms the sidewall covering above the lower partial thickness of the lower gate layer, i.e. only in the vicinity of the gate oxide layer. Since tungsten oxidation cannot occur in the case of the method according to the invention, the oxidation process can be carried out long enough to fabricate a sidewall oxide with the required thickness. Even in the case where the sidewall oxide grows between the mutually facing inner sides of the protective layers on both sides of the gate layer stack partly upward in the direction of the upper gate layer; the protective layer drawn into the lower gate layer prevents contact between tungsten or tungsten silicide and oxygen.

Preferably, a covering layer is deposited and, the protective layer is deposited with a thickness of less than 10 nm. The use of a nitride-containing covering layer having a thickness comparable to or greater than the upper or lower gate layer is known. However, on account of the protective layer that, according to the invention, is lengthened downward into the lower gate layer, the protective layer itself can be deposited significantly thinner, for example thinner than 10 or even 5 nm. On the top side, after the protective layer has been consumed, the sufficiently thick covering layer protects the gate layer stack during the remaining patterning of the lower gate layer. At the same time, the very thin protective layer reliably fulfills its function as oxidation protection, since it reaches into the lower gate layer to a sufficient depth. Irrespective of its thickness, it protects the upper gate layer not only against an oxidation but also against an alteration on account of deposited and etched-back polymers which have been deposited on account of cleaning agents or etchants employed.

Preferably, spacers are produced beside the sidewall coverings and the oxide. The spacers are produced in a conventional manner over the height of the entire gate layer stack and serve, particularly in the case of memory transistors disposed in pairs in a borderless contact configuration, for protection of the gate layer stacks during a subsequent source/drain contact etching.

With regard to the integrated circuit configuration mentioned in the introduction, the object on which the invention is based is achieved in that the sidewall coverings cover the sidewalls of the lower gate layer in an upper part of the layer thickness of the layer, and in that the lower edges of the sidewall coverings are disposed at a height above the gate oxide layer which corresponds to the remaining lower part of the layer thickness of the lower gate layer. The oxide extends more deeply into the lower gate layer in the lateral direction than the inner sides of the sidewall coverings, and the oxide extends even more deeply into the lower gate layer beyond the inner sides of the sidewall coverings by a distance which is smaller than the upper part of the layer thickness of the lower gate layer.

In a conventional circuit configuration with gate layer stacks that have sidewall coverings that do not extend over all the gate layers, the lower edges of the sidewall coverings are disposed above the gate oxide layer at a distance from it that corresponds precisely to the layer thickness of the lower gate layer. Consequently, the entire side wall of the lower gate layer is uncovered and would be oxidized during an oxidation. At the top side of the lower gate layer, the oxide would grow from the side into the polysilicon and, after growth beyond the layer thickness of the overlying sidewall covering, would finally reach the underside of the tungsten-containing upper gate layer or of the barrier layer. From there, tungsten would be oxidized and the gate electrode damaged.

According to the invention, therefore, the sidewall covering additionally covers an upper part of the lower gate layer, so that the lower edges of the sidewall coverings are removed from the gate oxide layer by a distance that is smaller than the layer thickness of the lower gate layer. In the case of a gate electrode of an integrated circuit configuration that is formed in this way, it is ensured that the upper gate layer, which is important for the conductivity of the gate electrode, is free of oxidation damage and, at the same time, impurity ions in the vicinity of the sidewalls of the lower gate layer are reliably bound into an oxidic environment and are thus spatially fixed. A gate electrode formed in this way functions entirely satisfactorily.

The sidewalls of the lower gate layer are oxidized to form an oxide below the sidewall coverings. According to the invention, it is provided that the oxide extends more deeply into the lower gate layer in the lateral direction than as far as the inner sides of the sidewall coverings. Therefore, the distance between the mutually facing inner sides of the left-hand and right-hand sidewall oxides can also be smaller than the distance between the mutually facing sides of the left-hand and right-hand sidewall coverings. On account of the height difference between the sidewall oxides and the upper gate layer, the height difference being achieved through the sidewall coverings that are lengthened into the lower gate layer, the upper gate layer, as well as a possible barrier layer, is always free of oxide.

According to the invention, it is provided, in particular, that the oxide extends even more deeply into the lower gate layer beyond the inner sides of the sidewall coverings by a distance which is smaller than the upper part of the layer thickness of the lower gate layer. In accordance with this embodiment, an oxidation of the upper gate electrode is completely precluded for geometrical reasons. Even in the assumed case where the grown sidewall oxide, after exceeding the thickness of the sidewall covering disposed above it, grew upward at the same growth rate as inward, the thickness of the sidewall oxide would be too small overall to allow it to reach the underside of the upper gate layer and tungsten oxide to form.

The height of the lower edges of the sidewall coverings above the gate oxide layer preferably amounts to between 10 and 90% of the layer thickness of the lower gate layer. In particular, it is preferred that the height of the lower edges above the gate oxide layer is at least 10 nm smaller than the layer thickness of the lower gate layer. These embodiments allow high conductivity values of the gate layer sequence even in the case of very thick sidewall oxides.

It is preferably provided that the lower gate layer is essentially composed of polysilicon and the upper gate layer is essentially composed of tungsten. The sidewall coverings are preferably composed of a nitride, in particular of silicon nitride.

It is preferably provided that the gate layer stack has a thin barrier layer between the upper and the lower gate layer, the sidewalls of which barrier layer are likewise covered by the sidewall coverings. Such a barrier layer is typically composed of tungsten nitride, titanium nitride or tantalum nitride and serves, during the deposition of tungsten on polysilicon, to prevent a chemical reaction between the two materials.

The patterned gate layer stack preferably forms the gate electrode of a transistor, preferably of a memory transistor of a volatile semiconductor memory. Accordingly, the integrated circuit configuration is preferably a DRAM or eDRAM (embedded dynamic random access memory).

Other features which are considered as characteristic for the invention are set forth in the appended claims.

Although the invention is illustrated and described herein as embodied in a method for fabricating a gate layer stack for an integrated circuit configuration, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1 to 6 are diagrammatic, sectional views showing a circuit configuration fabricated by a method according to the invention in different method stages;

FIG. 7 is a sectional view of a conventional circuit configuration;

FIG. 8 is a sectional view of a circuit configuration according to the invention; and

FIG. 9 is a sectional view of a DRAM with the circuit configuration according to the invention.

### DESCRIPTION OF THE PREFERRED EMBODIMENTS

The invention is based on a circuit configuration that usually contains a semiconductor substrate and a gate layer stack patterned thereon or on a gate oxide thereof. The method for fabricating the gate layer stack is described below.

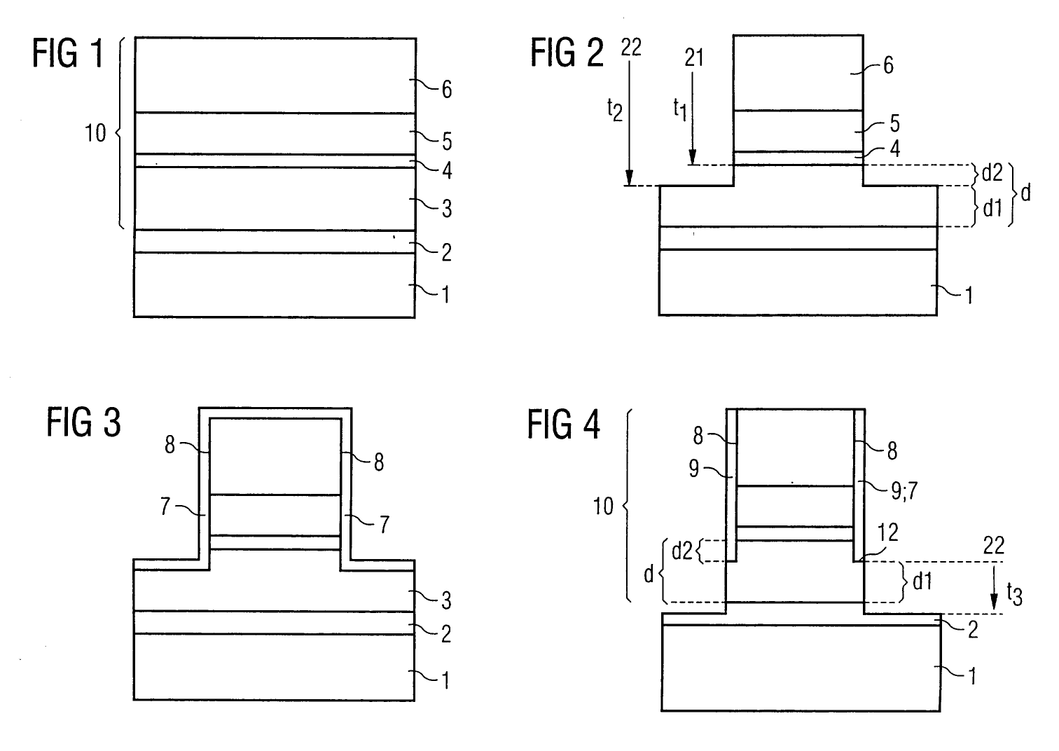

Referring now to the figures of the drawing in detail and first, particularly, to FIG. 1 thereof, there is shown on the semiconductor substrate which is illustrated as a bottommost layer 1 in FIG. 1, which semiconductor substrate 1 is then provided with the gate oxide layer 2 by oxidation on its upper area. Then layers 3 to 6 illustrated in FIG. 1 are successively deposited. A lower gate layer 3, which is generally composed of polysilicon, is deposited first. A thin barrier layer 4 may be deposited above it before an upper gate layer 5 is deposited. The barrier layer 4 serves, during subsequent process steps which require a temperature increase, to prevent a diffusion of silicon from the lower gate layer 3 made of polysilicon into the upper gate layer 5 made of a metal such as tungsten and to prevent chemical reactions with the material of the lower gate layer 3 that arise during the deposition of the upper gate layer 5. The barrier layer 4 is used in particular when tungsten is deposited as the upper gate layer 5. The upper gate layer 5 serves to increase the electrical conductivity of the gate layer stacks formed in the form of word lines that run laterally over the semiconductor substrate 1. The layer 5 is formed from a metal or at least from a metal silicide, if no tungsten is used. A covering layer 6 made of silicon nitride, for example, is deposited onto the upper gate layer 5, and protects the underlying layers during subsequent etching processes.

Such an etching process serves for patterning a layer sequence 10, which is initially deposited onto the semiconductor substrate 1 over the whole area, the nitride layer 6 deposited at the very top being used as an etching mask for the underlying layers. The patterning for forming gate electrodes is conventionally carried out in one step, provided that the upper gate layer 5 is not indeed composed of tungsten.

According to the invention, as illustrated as the result in FIG. 2, the gate layer stack 10 is initially patterned only partially. The partial patterning is subdivided into a first patterning step, in which the covering layer 6, the upper gate layer 5 and the barrier layer 4 are patterned with the aid of an anisotropic dry etching process in a time interval t1 using a first etchant 21 such as, for example, chlorine (reference symbol 21). Directly afterward, the lower gate layer 3 is etched in a second time interval t2 with the aid of a different, second etchant 22 such as, for example, hydrogen bromide. According to the invention, the etching of the lower gate layer using HBr is carried out initially only until reaching a first etching depth d2, which amounts to only part of the layer thickness d of the lower gate layer 3. Consequently, the gate layer stack 10 is patterned to approximately a middle of a height of the lower gate layer 3, as illustrated in FIG. 2. The residual thickness d1 situated underneath, in which the lower gate layer 3 is still present over the whole area of the semiconductor substrate 1, is not patterned directly afterward, according to the invention, but rather only after further method steps for producing sidewall coverings have elapsed.

For this purpose, as represented in FIG. 3, a nitride layer 7 is deposited onto the circuit configuration fabricated thus far. The deposition process is conformal and isotropic and serves primarily for covering sidewalls 8 of the upper gate layer 5, the covering layer 6, the barrier layer 4 and an upper part of the lower gate layer 3 with the continuous protective layer 7.

The nitride layer 7, as illustrated as the result in FIG. 4, is etched together with the remaining residual thickness of the lower gate layer 3 until at least the gate oxide layer 2 is reached. Preferably, the gate oxide layer 2 is also additionally etched at least over part of its thickness, which corresponds to the customary prolongation of the etching duration (over-etching), by which a layer to be patterned, such as in this case, for instance, the lower gate layer 3, is also reliably removed in steps of the semiconductor surface.

The etching of the protective layer 7 and of the residual lower gate layer 3 is done within a separate time interval t3 with the aid of the same etchant 22 that has already been used to etch the first partial thickness d1 of the lower gate layer 3. The structure formed as a result of the etching operation is represented in FIG. 4. It has a sidewall covering 9 at the sidewalls of the patterned gate layer stack 10 in that height over which the patterning has already taken place during the time intervals t1 and t2, which sidewall covering, in a similar manner to a spacer, laterally covers the sidewalls of the covering layer 6, of the upper gate layer 5, of the barrier layer 4 and of the lower gate layer 3 in an upper part d2 of its layer thickness and protects them against external influences.

Sidewalls 11 of the lower gate layer 3 are uncovered below lower edges 12 of the sidewall coverings 9, which are at a distance from the gate oxide layer 2 disposed below the gate layer stack 10 of the remaining residual thickness d1.

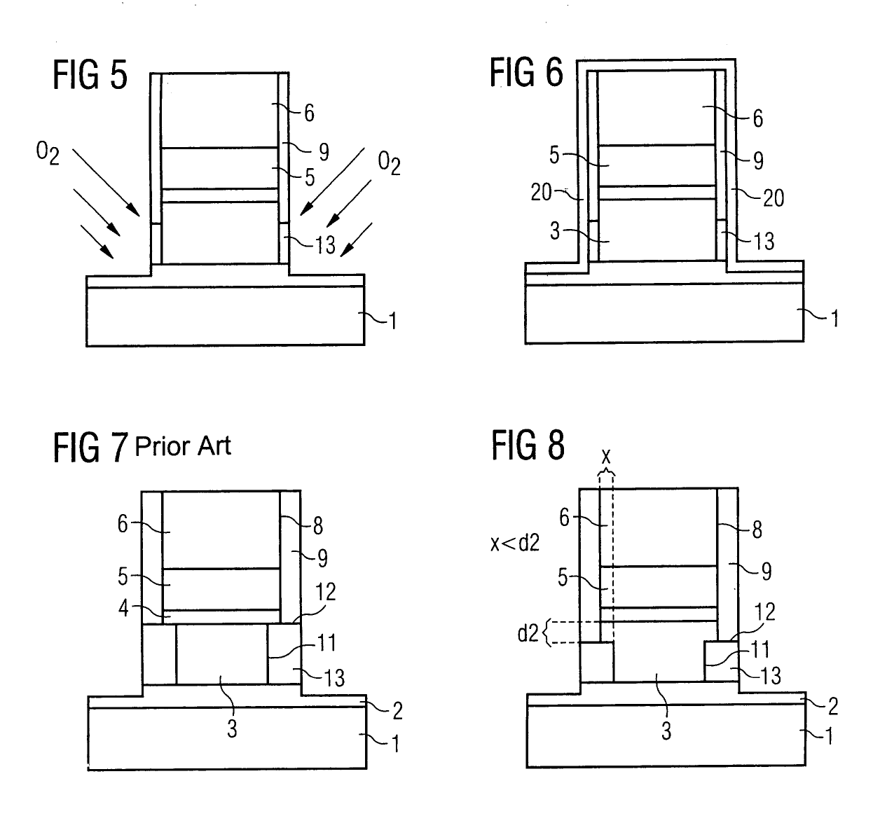

Then, in accordance with FIG. 5, an oxidation step is performed at elevated temperature in an oxygen-containing atmosphere, during which step the sidewalls of the lower gate layer 3, insofar as they are uncovered, are oxidized and thereby converted into silicon dioxide. At the same time, the oxide layer 2 is reinforced laterally outside the gate layer stack 15 (not represented in FIG. 5). If the upper gate layer 5 is composed of tungsten, the sidewall coverings 9 made of a nitride, for example, are necessary in order to protect the tungsten layer 5 during the oxidation. The latter layer, as can be seen in FIG. 5, is spatially separated from oxide regions 13 by the barrier layer 4 and the part of the sidewall coverings 9 that still additionally extends below the layer, so that oxidation also cannot take place through the lower gate layer 3.

Finally, the gate layer stack 10 that has been patterned in this way and treated by an oxidation is additionally covered with a spacer layer 20, as illustrated in FIG. 6. The layer 20 is typically likewise composed of silicon nitride and has the function of ensuring, during the implantation of source/drain electrodes, a sufficient lateral distance between introduced dopings and the channel region directly below the gate layer stack.

FIG. 7 shows a conventional gate layer stack 10 of an integrated circuit configuration, which stack has the sidewall covering 9 on the sidewalls 8 of the upper gate layer 5, of the covering layer 6 and of the barrier layer 4, which sidewall covering terminates at the lower edge 12 flush with the underside of the barrier layer 4. The sidewall coverings 9 were fabricated from a conformally deposited layer that was deposited directly after the etching of the covering layer 6, of the upper gate layer and of the barrier layer 4. Consequently, the lower edge 12 of the nitride liner 9 formed is situated on a level with the top side of the lower gate layer 3 made of polysilicon.

Sidewalls 11 of the polysilicon layer 3 are covered with the oxide region 13 that extends over the entire height of the lower gate layer 3. The oxide region 13 was grown directly after the complete patterning of the lower gate layer 3 and part of the polysilicon layer 2. The oxide region 13, namely silicon dioxide that was formed by oxidation of the polysilicon layer 3, has a larger width than the sidewall coverings 9 which cover the sidewalls of the upper layers. In particular, the oxide region 13 extends more deeply inward, i.e. into the center of the gate layer stack 10, from the side. This results in the oxide region 13 overlapping and making contact with the barrier layer 4, which is typically composed of tungsten silicide and, during thermal processes, fuses with the overlying upper gate layer 5 made of tungsten to form a uniform tungsten layer with a varying proportion of silicide. On account of the points of contact between the underside of the layer 4 and the overlapping region of the top side of the oxide region 13, during the oxidation process in accordance with the method stage from FIG. 5, oxidation of tungsten occurs and thus an uncontrolled reduction of the conductivity of the upper gate layer 5 occurs.

FIG. 8, in contrast, shows the patterned gate layer stack 10 of a circuit configuration according to the present invention. The sidewall coverings 9 extend below the underside of the barrier layer 4 additionally over the upper partial region d2 of the lower layer thickness d of the lower gate layer 3. They were not produced until after the lower gate layer 3 had also been patterned in its upper partial region d2. Consequently, the sidewall oxide region 13 was formed only in a lower partial region d1 of the layer thickness d of the polysilicon layer 3. As a result, the barrier layer 4 and the sidewall oxide regions 13 are spatially separated from one another by a layer made of the material of the lower gate layer 3 with a thickness of d2. As can be seen from FIG. 8, even in the case of a long oxidation process during which the sidewall oxide grows more deeply than as far as the inner sides 8 of the sidewall coverings 9 in the direction of the center of the lower gate layer 3, the tungsten-containing layers 4, 5 and the sidewall oxide region 13 do not come into contact and, consequently, oxidation of tungsten in the gate electrode 5 does not occur. In particular, it can be seen that the oxide region 13 extends even more deeply into the lower gate layer 3 than the inner sides of the sidewall coverings 9 by a distance x, which is smaller than the upper part d2 of the layer thickness d of the lower gate layer 3. The height of the lower gate layer 3 surrounded by the sidewall coverings 9 above the sidewall oxide regions 13 is greater than the difference between the lateral dimensions of the sidewall oxide region 13 and the sidewall covering 9. Therefore, an oxidation of the layers 4, 5 cannot take place even in the case where, from the inner side of the lower edge 12 of the sidewall coverings 9, the oxide 13 propagates in all directions, in particular including upward, at the same growth rate. Consequently, the gate electrode is not damaged.

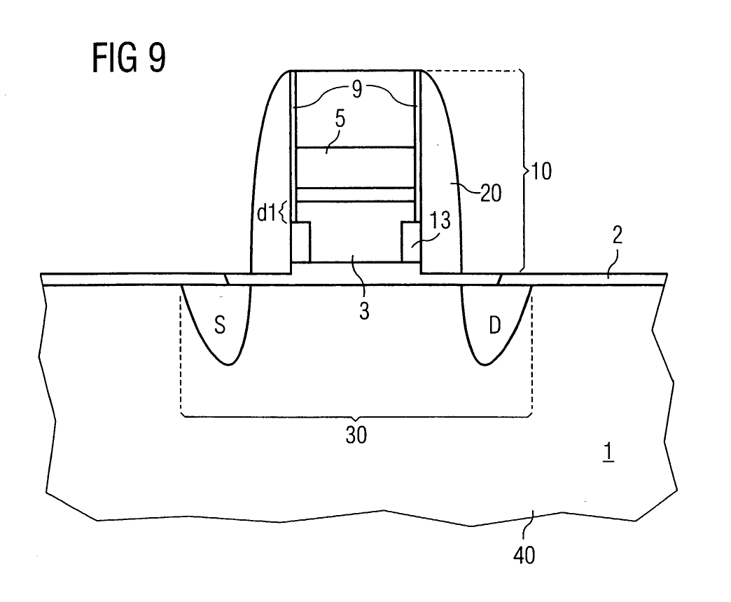

FIG. 9 shows a semiconductor memory 40, in particular a DRAM or an embedded DRAM, whose memory area has a transistor 30 with the circuit configuration according to the invention. The transistor 30 has, laterally outside the patterned gate layer stack 10, source and drain implantations S, D between which, at suitable voltages, a channel forms in the semiconductor substrate 1 directly at the bottom immediately below the gate oxide layer 2 below the gate layer stack 10. The sidewall coverings 9 disposed in the upper region of the gate layer stack 10 have a width of preferably between 3 and 15 nm and therefore turn out to be particularly thin. This is only possible because the sidewall coverings 9 also extend a certain distance d1 below the underside of the barrier layer 4 or of the upper gate layer 5. The sidewall oxide 13 present below the sidewall coverings 9 preferably has a thickness of between 5 and 20 nm. The spacers 20 outside the sidewall coverings 9 and the sidewall oxide 13 are typically significantly thicker. The electrical contacts for the electrodes of the transistor correspond to the prior art and are not illustrated in FIG. 9.

With the aid of the present invention, the sidewall oxidation that is used to prevent leakage currents into the silicon substrate and to spatially bind ions in the sidewalls of the lower gate layer 3 can be carried out for an even longer time than is conventional. The reason is that, on account of the height offset between the sidewall oxide 13 and the bottommost tungsten-containing gate layer 4 or 5, the layer boundaries of the bottommost tungsten-containing gate layer and of the sidewall oxide layers do not meet one another even in the case of a prolonged oxidation duration, i.e. in the case of prolonged growth of the sidewall oxide into the lower gate layer 3.

The present invention obviates the need to develop selective oxidation processes which could be used, under certain circumstances, to enable the lower gate layer 3 to be etched selectively with respect to tungsten-containing gate layers 4, 5. The encapsulation of the upper gate layer 5 and of the barrier layer 4 also at the height of an upper part of the lower gate layer 3 prevents incipient oxidation of tungsten.

We claim:

1. A method for fabricating a gate layer stack for an integrated circuit configuration, which comprises the steps of:
providing a semiconductor substrate;
forming a gate oxide layer on the semiconductor substrate;
depositing a lower gate layer on the gate oxide layer;
depositing an upper gate layer having a higher electrical conductivity than the lower gate layer above the lower gate layer;
patterning at least the upper gate layer resulting in a patterned upper gate layer;
patterning an upper part of a layer thickness of the lower gate layer;
depositing a protective layer at least onto sidewalls of the patterned upper gate layer and of the upper part of the layer thickness of the lower gate layer resulting in a formation of sidewall coverings, the lower gate layer, the upper gate layer, and the protective layer defining the gate layer stack; and
further patterning the gate layer stack at least until the gate oxide layer being reached and the lower gate layer being patterned only in a lower part of the layer thickness.

2. The method according to claim 1, which comprises exchanging a first etchant used for patterning the upper gate layer for a second etchant used for patterning the lower gate layer, and with the second etchant, the lower gate layer is patterned in the upper part of the layer thickness.

3. The method according to claim 2, which comprises patterning the gate layer stack by dry etching, and exchanging the first etchant being chlorine for the second etchant being hydrogen bromide.

4. The method according to claim 1, which comprises oxidizing sidewalls of the lower gate layer below lower edges of the sidewall coverings resulting in an oxide region.

5. The method according to claim 1, which comprises:
depositing a covering layer on the upper gate layer after the step of depositing the upper gate layer; and
depositing the protective layer with a thickness of less than 10 nm.

6. The method according to claim 4, which comprises producing spacers beside the sidewall coverings and the oxide region.

7. An integrated circuit configuration, comprising:
a semiconductor substrate;
a gate oxide layer disposed on said semiconductor substrate;
a patterned gate layer stack disposed on said semiconductor substrate, said patterned gate layer stack having a lower gate layer disposed above said gate oxide layer, and an upper gate layer having a higher electrical conductivity than said lower gate layer, said lower gate layer and said upper gate layer having side walls;
sidewall coverings covering at least said sidewalls of said upper gate layer and an upper part of a layer thickness of said lower gate layer, said sidewall coverings having lower edges disposed above said gate oxide layer and at a distance from said gate oxide layer, said lower edges of said sidewall coverings are disposed at a height above said gate oxide layer corresponding to a remaining lower part of said layer thickness of said lower gate layer; and
an oxide region extending more deeply into said lower gate layer in a lateral direction than inner sides of said sidewall coverings, said oxide region extending even more deeply into said lower gate layer beyond said inner sides of said sidewall coverings by a distance being smaller than said upper part of said layer thickness of said lower gate layer.

8. The circuit configuration according to claim 7, wherein the height of said lower edges of said sidewall coverings above said gate oxide layer amounts to between 10 and 90% of said layer thickness of said lower gate layer.

9. The circuit configuration according to claim 7, wherein the height of said lower edges of said sidewall coverings above said gate oxide layer is at least 10 nm smaller than said layer thickness of said lower gate layer.

10. The circuit configuration according to claim 7, wherein said side walls of said lower gate layer are oxidized to form said oxide region below said sidewall coverings.

11. The circuit configuration according to claim 7, wherein said lower gate layer is formed of polysilicon and said upper gate layer is formed of tungsten.

12. The circuit configuration according to claim 7, wherein said sidewall coverings are formed of a nitride.

13. The circuit configuration according to claim 7, wherein said patterned gate layer stack has a thin barrier layer disposed between said upper gate layer and said lower gate layer, said barrier layer having side walls covered by said sidewall coverings.

14. The circuit configuration according to claim 7, wherein said patterned gate layer stack forms a gate electrode of a transistor.

15. The circuit configuration according to claim 14, wherein said transistor is a memory transistor of a volatile semiconductor memory.
